(19) United States
(12) Patent Application Publication
(10) Pub. No.: US 2024/0146284 A1
(43) Pub. Date: May 2, 2024

(54) QUARTZ-CRYSTAL VIBRATING PIECE AND QUARTZ CRYSTAL DEVICE USING THE SAME

(71) Applicant: NIHON DEMPA KOGYO CO., LTD., Tokyo (JP)

(72) Inventors: Koji TOSHIKAWA, Saitama (JP); Takashi YAMAGUCHI, Saitama (JP)

(73) Assignee: NIHON DEMPA KOGYO CO., LTD., Tokyo (JP)

(21) Appl. No.: 18/493,784

(22) Filed: Oct. 24, 2023

(30) Foreign Application Priority Data
Oct. 26, 2022 (JP) 2022-171200
Jul. 7, 2023 (JP) 2023-112278

(51) Int. Cl. H03H 9/19; H03H 9/02; H03H 9/05; H03H 9/10

(52) U.S. Cl. CPC H03H 9/19; H03H 9/02023; H03H 9/0557; H03H 9/1021

(57) ABSTRACT

An AT-cut quartz-crystal vibrating piece includes a vibrator, a peripheral portion, and a level difference. The peripheral portion has a thickness thinner than a thickness of the vibrator. The level difference is on each of a front and a back of the quartz-crystal vibrating piece. The level difference is generated caused by a thickness difference between the vibrator and the peripheral portion. When a dimension along an X-axis of a crystal of the quartz-crystal vibrating piece is defined as Lx, a dimension along a Z′-axis of the crystal of the quartz-crystal vibrating piece is defined as Lz, a thickness of the vibrator is defined as t, and a height of the level difference is defined as d, Lx is in a range from 849 to 857 μm, Lz is in a range from 625 to 645 μm, and d/t is in a range of 0.094≤d/t≤0.11.

### CROSS-REFERENCE TO RELATED APPLICATIONS

This application is based on and claims priority under 35 U.S.C. § 119 to Japanese Patent Application Nos. 2022-171200, filed on Oct. 26, 2022, and 2023-112278, filed on Jul. 7, 2023, the entire contents of which are incorporated herein by reference.

### TECHNICAL FIELD

This disclosure relates to a quartz-crystal vibrating piece with what is called a mesa type structure, which has a vibrator in a protruding shape, and a quartz crystal device using the same.

### DESCRIPTION OF THE RELATED ART

As one type of quartz-crystal vibrating piece that vibrates in a thickness-shear mode of vibration, there is one with a structure having a vibrator of the quartz-crystal vibrating piece protruding compared with other portions. That is a quartz-crystal vibrating piece with what is called a mesa type structure. Compared with a case otherwise, this structure can efficiently confine vibration energy in the vibrator, thereby achieving property improvement in the quartz-crystal vibrating piece.

An exemplary quartz-crystal vibrating piece of this type is disclosed in, for example, Japanese Patent No. 5459352. This quartz-crystal vibrating piece is in a quadrilateral shape in plan view and includes a vibrator, a peripheral portion having a thickness thinner than that of this vibrator, and excitation electrodes disposed on a front and a back of the vibrator.

Moreover, when a dimension along a vibration direction of a thickness shear vibration is x, a thickness dimension of the vibrator is t, a dimension along the vibration direction of the vibrator is Mx, a dimension along the vibration direction of the excitation electrode is Ex, and a wavelength of a flexure vibration that occurs along the vibration direction is k, this quartz-crystal vibrating piece has these x, t, Mx, Ex, and λ, in a predetermined relationship (for example, claim 1 in Japanese Patent No. 5459352).

With this quartz-crystal vibrating piece, it is said that crystal impedance (CI) can be reduced, and a quartz-crystal vibrating piece with a high design margin can be achieved (for example, paragraph 7 in Japanese Patent No. 5459352).

Quartz-crystal vibrating pieces that vibrate in a thickness-shear mode have various kinds of frequencies and sizes depending on usage. Moreover, since crystals have delicate physical properties, structures of the quartz-crystal vibrating pieces with which desired properties can be obtained often differ depending on differences in frequencies and sizes of the quartz-crystal vibrating pieces. Therefore, the structures of the quartz-crystal vibrating pieces need to be optimized for each quartz-crystal vibrating piece with a different frequency and size.

For example, an AT-cut quartz-crystal vibrating piece for a frequency band near 24 MHz that can be housed within a small-sized package having an outer dimension with a long side dimension of approximately 1.2 mm and a short side dimension of approximately 1.0 mm is also required to have a structure exhibiting a practical electrical performance. This is because the AT-cut quartz-crystal vibrating piece for the frequency band near 24 MHz is important as a reference signal source for various kinds of communication terminals typified by mobile phones. Similarly, a quartz-crystal vibrating piece for a frequency band near 32 MHz is also required to have a structure that can be housed within a small-sized package as described above and that exhibits a practical electrical performance.

A need thus exists for a quartz-crystal vibrating piece and a quartz crystal device using the same which are not susceptible to the drawback mentioned above.

### SUMMARY

According to an aspect of this disclosure, there is provided an AT-cut quartz-crystal vibrating piece having an oscillation frequency of 24 MHz and a planar shape in a rectangular shape. The AT-cut quartz-crystal vibrating piece includes a vibrator, a peripheral portion having a thickness thinner than a thickness of the vibrator, and a level difference on each of a front and a back of the quartz-crystal vibrating piece. The level difference is generated caused by a thickness difference between the vibrator and the peripheral portion. When a dimension along an X-axis of a crystal of the quartz-crystal vibrating piece is defined as Lx, a dimension along a Z′-axis of the crystal of the quartz-crystal vibrating piece is defined as Lz, a thickness of the vibrator is defined as t, and a height of the level difference is defined as d, Lx is in a range from 849 to 857 μm, Lz is in a range from 625 to 645 μm, and d/t is in a range of 0.094≤d/t≤0.11.

Note that 24 MHz mentioned in this disclosure includes, not to mention the case of exactly 24 MHz, frequencies near 24 MHz, for example, frequencies of 24.305 MHz, 24.545 MHz, 24.576 MHz, and the like, which are used as a reference signal source and the like for various kinds of electronic equipment.

### BRIEF DESCRIPTION OF THE DRAWINGS

The foregoing and additional features and characteristics of this disclosure will become more apparent from the following detailed description considered with reference to the accompanying drawings, wherein:

FIG. 1A to FIG. 1D are explanatory drawings of a quartz-crystal vibrating piece 10 and a quartz crystal device according to an embodiment;

FIG. 2A to FIG. 2C are drawings for describing preferred ranges of dimensions Lx and Lz of a quartz-crystal vibrating piece according to this disclosure;

FIG. 3A to FIG. 3C are drawings continuing from FIG. 2A to FIG. 2C for describing the preferred ranges of the dimensions Lx and Lz of the quartz-crystal vibrating piece according to this disclosure;

FIG. 4A and FIG. 4B are drawings continuing from FIG. 3A to FIG. 3C for describing the preferred ranges of the dimensions Lx and Lz of the quartz-crystal vibrating piece according to this disclosure;

FIG. 5 is a drawing for describing a preferred range of d/t of the quartz-crystal vibrating piece according to this disclosure;

FIG. 6 is a drawing for describing a preferred example of the quartz-crystal vibrating piece according to this disclosure;

FIG. 7A and FIG. 7B are drawings for describing another preferred example of the quartz-crystal vibrating piece according to this disclosure;

FIG. 8A and FIG. 8B are drawings continuing from FIG. 7A and FIG. 7B for describing the other preferred example of the quartz-crystal vibrating piece according to this disclosure;

FIG. 9A and FIG. 9B are drawings for describing another example of the quartz crystal device according to this disclosure; and

FIG. 10 is a drawing continuing from FIG. 9A and FIG. 9B for describing the other example of the quartz crystal device according to this disclosure.

### DETAILED DESCRIPTION

The following describes embodiments of a quartz-crystal vibrating piece and a quartz crystal device according to this disclosure with reference to the drawings. Each drawing used in the description is merely illustrated schematically for understanding this disclosure. In each drawing used in the description, identical reference numerals designate similar components, and therefore explanations thereof may be omitted. Shapes, dimensions, materials, and similar factors described in the following description are merely preferable examples within the scope of this disclosure. Therefore, this disclosure is not limited to only the following embodiments.

### 1. Embodiment of 24 MHz Quartz-Crystal Vibrating Piece and Quartz Crystal Device

### 1-1. Structure

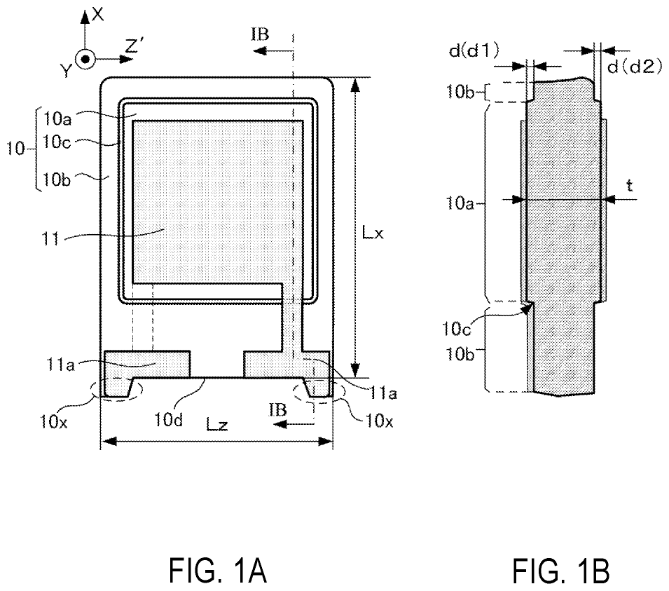

First, with reference to FIG. 1A and FIG. 1B, a quartz-crystal vibrating piece 10 according to an embodiment with an oscillation frequency of 24 MHz will be described.

FIG. 1A is a plan view of the quartz-crystal vibrating piece 10 according to the embodiment, and FIG. 1B is a sectional view of the quartz-crystal vibrating piece 10 taken along the line IB-IB in FIG. 1A. The coordinate axes X, Y, and Z′ in FIG. 1A to FIG. 1D correspond to crystallographic axes X, Y, and Z′-axes of respective crystals. Note that Z′ means a predetermined angle deviation from a Z-axis of a crystal caused by a cut angle of the AT-cut quartz-crystal vibrating piece 10.

The quartz-crystal vibrating piece 10 according to the embodiment is an AT-cut quartz-crystal vibrating piece that has an oscillation frequency of 24 MHz and a planar shape in a rectangular shape, and includes a vibrator 10a, a peripheral portion 10b having a thickness thinner than that of the vibrator 10a, and a level difference 10c on each of a front and a back of the quartz-crystal vibrating piece 10 being generated caused by a thickness difference between the vibrator 10a and the peripheral portion 10b.

Moreover, when a dimension along the X-axis of the crystal of the quartz-crystal vibrating piece is defined as Lx, a dimension along the Z′-axis of the crystal of the quartz-crystal vibrating piece is defined as Lz, a thickness of the vibrator is defined as t, and a height of the level difference is defined as d, the quartz-crystal vibrating piece 10 has:
Lx in a range from 849 to 857 μm,
Lz in a range from 625 to 645 μm, and more preferably 630 to 638 μm, and
d/t in a range of 0.094≤d/t≤0.11.

Note that when heights of the level differences of the front and the back of the quartz-crystal vibrating piece are defined as d1 and d2 (see FIG. 1B), d1 and d2 are typically the same in practice. However, d1 and d2 may be different within a range where the object of this disclosure is not impaired.

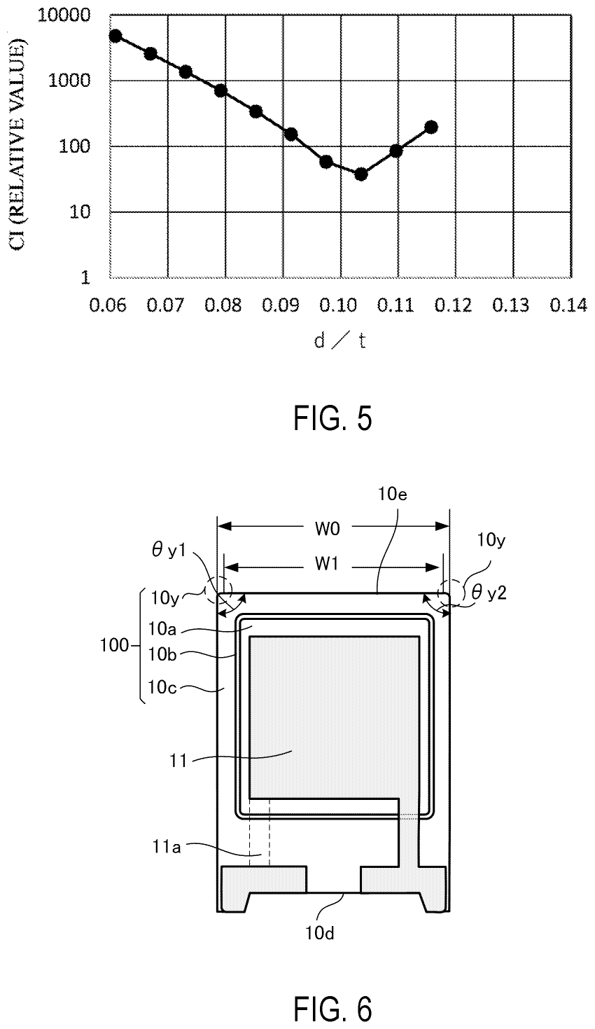

When a short side, on a side secured to a container 31 (see FIG. 1C) housing the quartz-crystal vibrating piece 10, of two short sides of the quartz-crystal vibrating piece 10 is defined as a securing-side short side 10d, and a short side on the opposite side is defined as a distal-end-side short side 10e, both corner portions of the distal-end-side short side 10e may be rounded or may be approximately right-angled as described later using FIG. 6.

The vibrator 10a is in a quadrilateral shape in plan view, and is in a rectangular shape in the case of this embodiment. The vibrator 10a, however, may have a planar shape in a square shape, or in another case, may have a planar shape in a circular shape or an elliptical shape. A size of the vibrator 10a and a position of the vibrator 10a relative to the quartz-crystal vibrating piece 10 can be conveniently set corresponding to the design of the quartz-crystal vibrating piece 10, and one example thereof will be described in the paragraph of the experimental results below.

Each of the front and the back of the quartz-crystal vibrating piece 10 includes an excitation electrode 11 and an extraction electrode 11a. In this embodiment, the excitation electrode 11 is disposed to fit within a region of the vibrator 10a and is in a quadrilateral shape in plan view, which is in a rectangular shape in the case of this embodiment, but may be in a circular shape or an elliptical shape in some cases. A size of the excitation electrode 11 and a position of the excitation electrode 11 relative to the vibrator 10a can be conveniently set corresponding to the design of the quartz-crystal vibrating piece 10, and one example thereof will be described in the paragraph of the experimental results below.

The extraction electrode 11a is extracted from a part of the excitation electrode 11 to a side of the securing-side short side 10d of the quartz-crystal vibrating piece 10. The excitation electrode 11 and the extraction electrode 11a can be configured of any given preferred metal film.

Note that, in FIG. 1A to FIG. 1D, protruding shape portions 10x protruding downward in the drawing from the securing-side short side 10d of the quartz-crystal vibrating piece 10 originate from a situation in which a plurality of the quartz-crystal vibrating pieces 10 are formed on a crystal wafer (not illustrated) by a photolithography technique, and are portions remaining when each of the quartz-crystal vibrating pieces 10 is broken off from the crystal wafer. The protruding shape portion 10x is not necessary, but can contribute to improved adhesive strength when the quartz-crystal vibrating piece 10 is secured to the container 31 with a conductive adhesive 33.

Next, with reference mainly to FIG. 1C and FIG. 1D, a quartz crystal device according to the embodiment will be described. FIG. 1C is a plan view of the quartz crystal device according to the embodiment, and FIG. 1D is a side view of the quartz crystal device.

The quartz crystal device according to the embodiment is an example of a crystal unit 30 including the container 31, the conductive adhesive 33, a lid member 35, and the above-described quartz-crystal vibrating piece 10.

The container 31 includes a depressed portion 31a in a rectangular shape in plan view that can contain the quartz-crystal vibrating piece 10, a dike 31b that surrounds a peripheral area of the depressed portion 31a, a connection pad 31c disposed in a part of a bottom surface of the depressed portion 31a, and an external connecting terminal 31d disposed on an external bottom surface of the container 31. The connection pad 31c is connected and secured to the quartz-crystal vibrating piece 10. The connection pad 31c is connected to the external connecting terminal 31d by via-wiring or the like (not illustrated). This container 31 can be configured of, for example, a known ceramic package.

The quartz-crystal vibrating piece 10 is mounted within the depressed portion 31a of the container 31. Specifically, the quartz-crystal vibrating piece 10 is connected and secured to the connection pad 31c of the container 31 at a position of the extraction electrode 11a on the side of the securing-side short side 10d with the conductive adhesive 33. Accordingly, the quartz-crystal vibrating piece 10 is secured to the container 31 in what is called a cantilever support structure.

The dike 31b of the container 31 is connected to the lid member 35 with any given preferred sealing method. As a result, the quartz-crystal vibrating piece 10 is sealed in an airtight state within the container 31. Note that the inside of the depressed portion 31a of the container 31 has a reduced-pressure atmosphere, a nitrogen atmosphere, or an inert gas atmosphere.

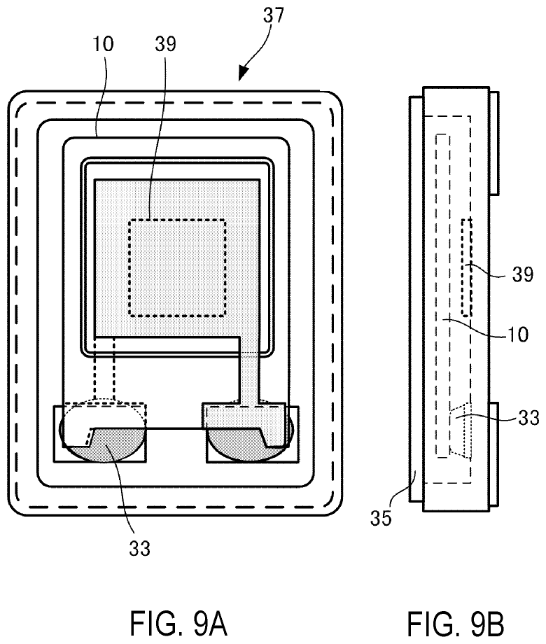

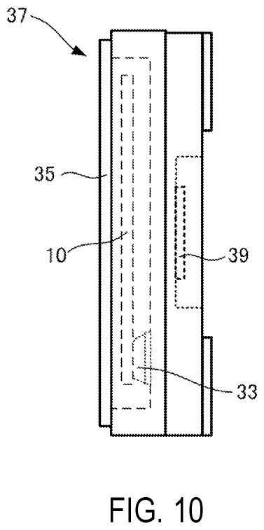

Note that while the example of the crystal unit 30 as a quartz crystal device has been described here, a quartz crystal device 37 that includes the quartz-crystal vibrating piece 10 and yet another functional element 39 may be employed as in a plan view illustrated in FIG. 9A and in a side view illustrated in FIG. 9B. Specifically, what is called a temperature-sensor-provided crystal unit that includes the quartz-crystal vibrating piece 10 of this disclosure and a temperature sensor (for example, a thermistor) as the other functional element 39 may be employed. The other functional element 39 may be a crystal controlled oscillator serving as an oscillator circuit for the quartz-crystal vibrating piece 10. The other functional element 39 may be a temperature compensation type crystal controlled oscillator or the like serving as an IC or the like including an oscillator circuit for the quartz-crystal vibrating piece of this disclosure, a temperature sensor for temperature compensation, and a temperature compensation circuit. While FIG. 9A and FIG. 9B illustrate a structural example in which the quartz-crystal vibrating piece 10 and the functional element 39 are mounted in one room, a structure in which the quartz-crystal vibrating piece 10 and the functional element 39 are mounted in different rooms as illustrated in a sectional view in FIG. 10, which is what is called an H-shaped structure when viewed in cross section, may be employed.

### 1-2. Experiment and Simulation

### 1-2-1. Lx and Lz

Next, the dimensions Lx and Lz of the quartz-crystal vibrating piece 10, the relationship between the thickness t of the vibrator 10a and the height d of the level difference 10c, and the like claimed in this disclosure will be described.

The inventors of this application experimentally produced respective quartz-crystal vibrating pieces with the dimension Lx along the X-axis of the crystal of the quartz-crystal vibrating piece 10 of five levels of 845 μm, 849 μm, 853 μm, 857 μm, and 861 μm and the dimension Lz along the Z′-axis of the crystal of four levels of 626 μm, 630 μm, 634 μm, and 638 μm with respect to these five respective levels. For Lx at the level of 849 μm, however, a level between 620 and 626 μm and a level between 639 and 654 μm were added in addition to the above-described four Lz levels, and thus, the quartz-crystal vibrating pieces were experimentally produced.

Note that, upon the experimental production of these, the X dimension of the vibrator 10a included in the quartz-crystal vibrating piece 10 was 547 μm and the Z′ dimension was 515 μm, and the X dimension of the excitation electrode 11 was 449 μm and the Z′ dimension was 462 μm. The height d of the level difference 10c to the thickness t of the vibrator was a value that satisfied d/t=0.1. The reason of d/t being 0.1 will be described later. Note that the directions of the X dimension and the Z′ dimension are respective directions parallel to the directions of the Lx dimension and the Lz dimension.

The positions of the vibrator 10a and the excitation electrode 11 with respect to the quartz-crystal vibrating piece 10 were positions where respective planar center points α (see FIG. 1C) of the vibrator 10a and the excitation electrode 11 were decentered by 85 μm in a direction of the distal end of the quartz-crystal vibrating piece 10 with respect to a planar center point β (see FIG. 1C) of the quartz-crystal vibrating piece 10.

Using the quartz-crystal vibrating pieces experimentally produced on such conditions, the crystal units 30 in the structure illustrated in FIG. 1C as one example of the quartz crystal device were experimentally produced.

Next, respective degrees of variations of crystal impedance (CI) relative to an ambient temperature, that is, respective temperature characteristics of the CI of these experimentally produced crystal units 30 were measured. Note that the measurement temperature range was a range from −40° C. to 125° C., and the measurement temperature step was 1° C.

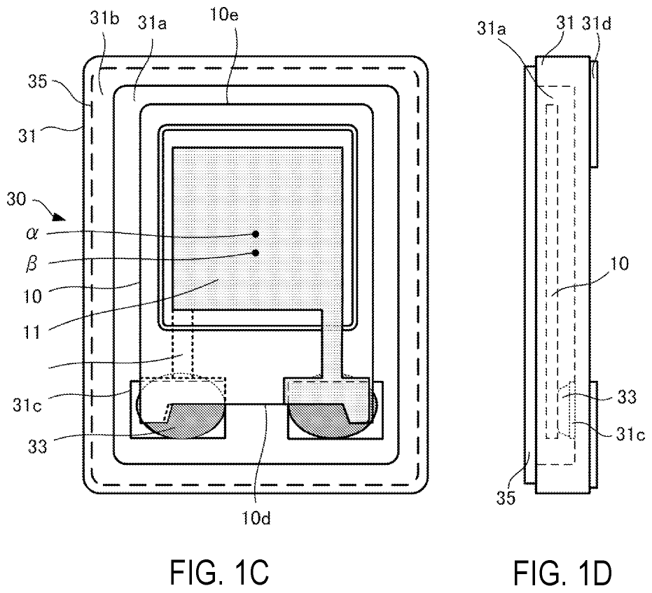

From these measurement results, a preferred range of the Lz dimension was examined. FIG. 2A is a drawing illustrating relationships between the CI and the Lz dimensions illustrated by focusing on the CI at room temperature of the respective crystal units with the Lx dimension of 857 μm and the Lz dimensions of the above-described four levels in the experimentally produced crystal units. FIG. 2B is a drawing illustrating relationships between the CI at room temperature and the Lz of the respective quartz crystal units with the Lx dimension of 853 μm and the Lz dimensions of the above-described four levels. FIG. 2C is a drawing illustrating relationships between the CI at room temperature and the Lz of the respective crystal units with the Lx dimension of 849 μm and the Lz dimensions in a wide dimensional range including the above-described four levels and the added levels described above. All the drawings are drawings having the horizontal axes indicating the Lz dimensions (μm) and the vertical axes indicating the CI (Ω). The CI values, however, are indicated by relative values compared with the reference CI value.

When the upper limit of the CI standard of the crystal unit 30 is 2 in a relative value of a CI value, it can be seen that the Lz dimension that can fulfill this standard is preferably 625 to 645 μm, and more preferably 630 to 638 μm, as can be seen from FIG. 2A to FIG. 2C.

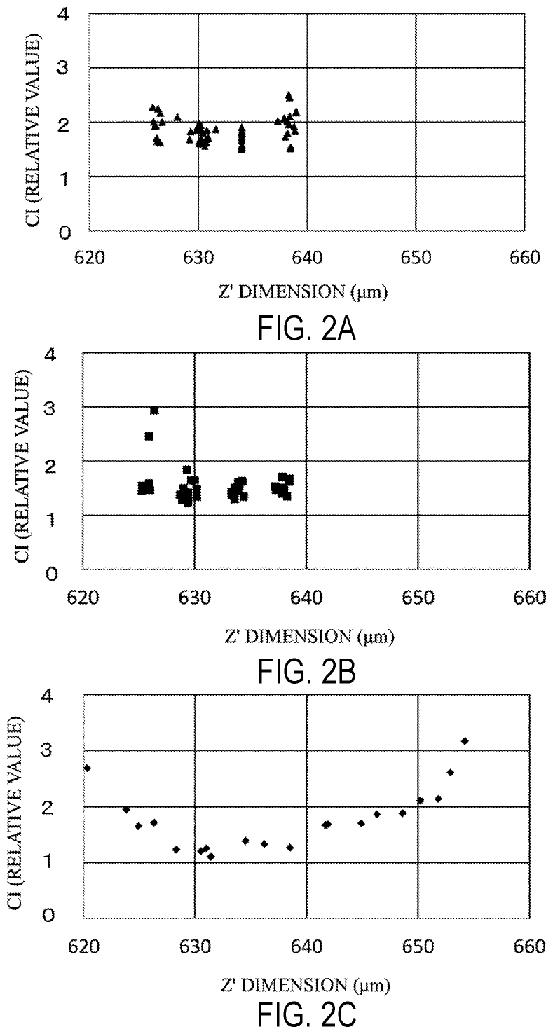

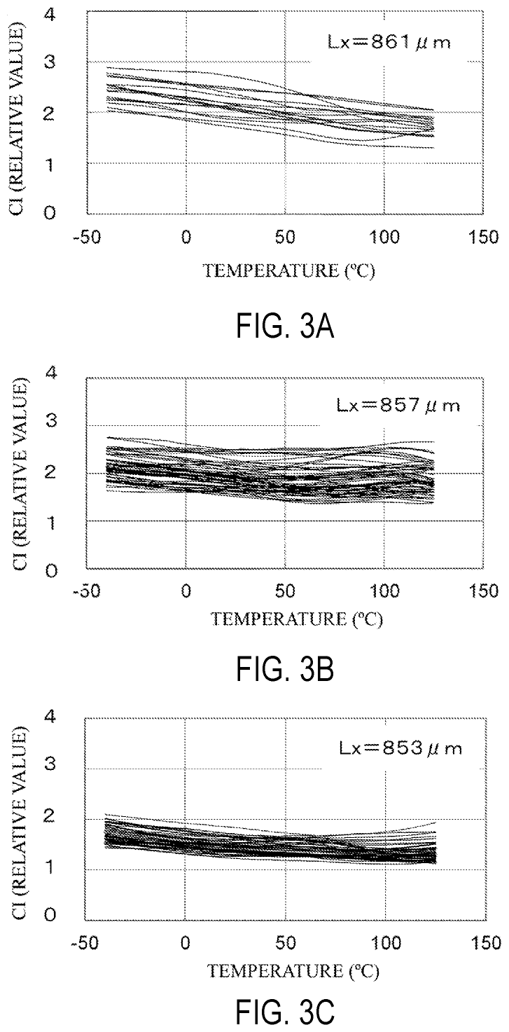

From the above-described measurement results, a preferred range of the Lx dimension was examined. FIG. 3A to FIG. 3C and FIG. 4A and FIG. 4B are drawings illustrating relationships between temperatures and CI of the respective crystal units with the Lz dimension of 630 μm and the Lx dimensions of the above-described five levels in the experimentally produced crystal units. Specifically, FIG. 3A is a relationship drawing described above when the Lx dimension is 861 μm, FIG. 3B is a relationship drawing described above when the Lx dimension is 857 μm, FIG. 3C is a relationship drawing described above when the Lx dimension is 853 μm, FIG. 4A is a relationship drawing described above when the Lx dimension is 849 μm, and FIG. 4B is a relationship drawing described above when the Lx dimension is 845 μm.

In the relationship between the temperatures and the CI, the CI value within the measurement temperature range of the crystal unit is preferably small and the variation of the CI within the measurement temperature range of one crystal unit is preferably small. When the upper limit of the CI value within the measurement temperature range of the crystal unit 30 is 2.5 in a relative value of a CI value and the allowable width of the variation of the CI in the temperature range from −40 to 125° C. for each quartz crystal device is 0.15 in a relative value of a CI value, it can be seen that those that fulfill this standard are those with the Lx dimension of 849 to 861 μm, and it can be seen that those with the Lx dimension of 849 to 857 μm are more preferred.

### 1-2-2. Height d of Level Difference and Thickness t of Quartz-Crystal Vibrating Piece

By the finite element method, a preferred range of d/t was analyzed. The analysis was performed by creating a plurality of analytical models as the quartz-crystal vibrating piece 10 illustrated in FIG. 1A, with the Lx dimension of 853 μm, the Lz dimension of 630 μm, and d/t of various levels of 0.061, 0.067, 0.073, 0.079, 0.085, 0.091, 0.097, 1.04, 1.1, and 1.16, and extracting the respective CI (crystal impedance).

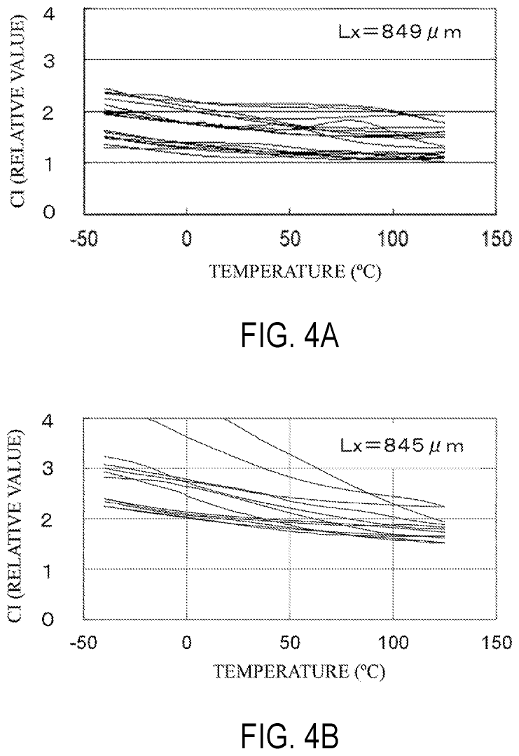

FIG. 5 is a drawing with the horizontal axis indicating d/t and the vertical axis indicating the relative value of the CI value relative to a certain reference value of the CI, and illustrating a relationship between d/t and the relative value of the CI value. From FIG. 5, it can be seen that, as the level difference increases, the CI decreases, and the CI provides the lowest value near 0.1 in d/t, but when the level difference is further increased (when d/t is increased), the CI shifts to increase. The reason of the CI increase when d/t is larger than 0.1 is presumed to be the effect of unnecessary vibration.

When the upper limit of the CI standard is 100 in a relative value of a CI value, it can be seen from FIG. 5 that d/t is preferably 0.094≤d/t≤0.11.

### 2. Shape of Both Corner Portions of Distal End of Quartz-Crystal Vibrating Piece

Although there has been described above that the corner portions of the distal end side of the quartz-crystal vibrating piece may be rounded or may be approximately right-angled, the corner portions of the distal end side of the quartz-crystal vibrating piece are preferably approximately right-angled when ensuring a planar size of the quartz-crystal vibrating piece. The description thereof will be given with reference to FIG. 6. Note that FIG. 6 is a plan view similar to FIG. 1A.

When the angles formed by the distal-end-side short side 10e of a quartz-crystal vibrating piece 100 and long sides of the quartz-crystal vibrating piece 100 are defined as θy1 (θy2), θy1 (θy2) are preferably approximately right-angled, and specifically, are preferably angles in a range from 85 to 90 degrees. Such shapes improve the CI (crystal impedance) compared with a case otherwise. The reason is that, when the distal end corner portions of the quartz-crystal vibrating piece 100 are approximately right-angled, the long side dimension Lx of the quartz-crystal vibrating piece 100 is effectively lengthened, and therefore, it is considered to be effective in energy confinement of the main vibration. This effect is considered to be effective as the quartz-crystal vibrating piece is decreased in size.

Note that the angles θy1 and θy2 may be the same or may be different. From a different aspect from the angles θy1 and θy2, when an average dimension of the dimensions along the Z′-axis of the crystal of the quartz-crystal vibrating piece 100 is defined as W0 and a length of a linear portion in the distal-end-side short side 10e is defined as W1, W1/W0 is preferably 0.93 to 0.99.

### 3. Examination of Z′ Dimension Lz of Quartz-Crystal Vibrating Piece

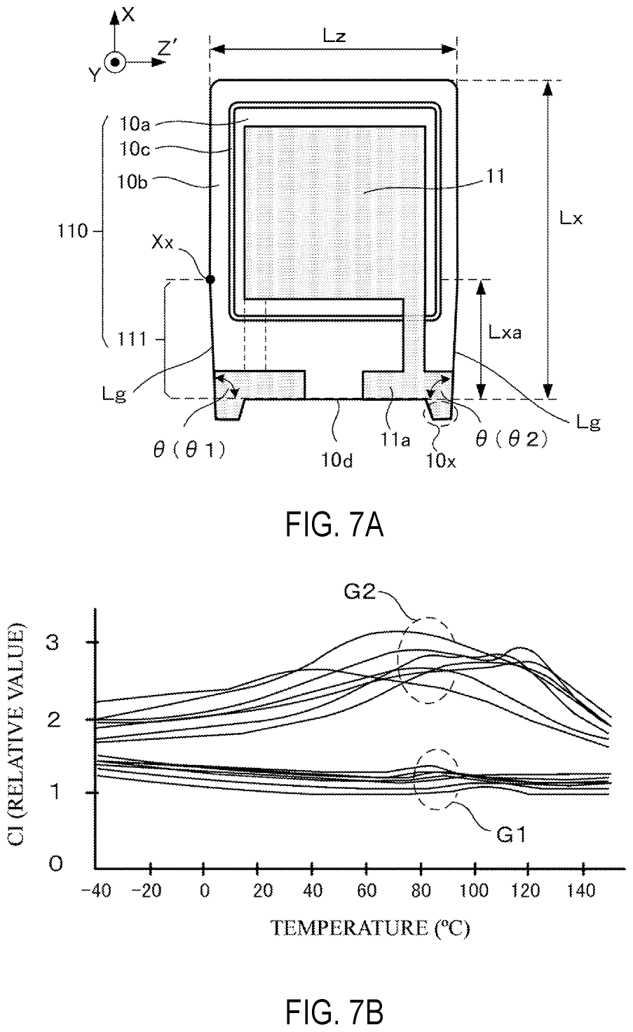

According to the examination by the inventors of this application, as described with reference to FIG. 7A, it is found that, when the dimension Lz of a quartz-crystal vibrating piece 110 is decreased from a midpoint Xx along the X-axis of the crystal toward the securing-side short side 10d of the quartz-crystal vibrating piece, property improvement of the quartz-crystal vibrating piece 110 can be achieved compared with a case otherwise. The following describes this respect. FIG. 7A is a plan view of the quartz-crystal vibrating piece 110 therefor.

The quartz-crystal vibrating piece 110 includes a width reduction portion 111 of the Z′ dimension, which is the dimension Lz in the Z′-direction being decreased from the midpoint Xx along the X-axis toward the securing-side short side 10d of the quartz-crystal vibrating piece 110. Moreover, when a contour in the X-axis direction of the crystal of the width reduction portion 111 of the Z′ dimension is viewed, the contour is in a straight line, and when this straight line is defined as a width reduction contour line Lg, an angle θ (angle θ1, θ2) formed by the width reduction contour line Lg and the Z′-axis of the crystal is θ=93±2°. θ can be optimized corresponding to the design of the quartz-crystal vibrating piece 110, and can be adjusted by changing, for example, a photomask dimension for producing the quartz-crystal vibrating piece 110, a wet etching period when the outer shape of the quartz-crystal vibrating piece 110 is formed, and the like. Note that the angles θ1 and θ2 may be the same or may be different. According to the examination by the inventors, θ is preferably θ=93±1°.

The width reduction contour line Lg occurs at both ends in the Z′-direction of the quartz-crystal vibrating piece 110. Here, while where to put the midpoint Xx can be determined in consideration of the property improvement of the quartz-crystal vibrating piece 110, according to the experiment by the inventors of this application, it has already been found that, when the dimension along the X-axis of the crystal from the securing-side short side 10d of the midpoint Xx is defined as Lxa, Lxa to the long side dimension Lx of the quartz-crystal vibrating piece 110 is preferably a value in a range of Lxa/Lx=0.32 to 0.42. In the case of FIG. 7A, Lxa/Lx=0.37. When viewed from another aspect, it is considered that the midpoint Xx may be near an edge portion of the vibrator 10a.

FIG. 7B is a drawing illustrating temperature characteristics of the CI of the crystal unit in the example including the width reduction portion 111 in the Z′-direction and of a crystal unit in a comparative example having a structure similar to that of the example except that the width reduction portion 111 in the Z′-direction is not provided together. In FIG. 7B, the horizontal axis indicates the temperature, and the vertical axis indicates the relative value of the CI.

In FIG. 7B, the group to which G1 is attached is the temperature characteristic of the CI of the example, and the group to which G2 is attached is the temperature characteristic of the CI of the comparative example. From FIG. 7B, it can be seen that, compared with the comparative example, the crystal unit of the example has a small absolute value of the CI by approximately half, and moreover, the CI variation degree to the temperature for each crystal unit can also be reduced by half or less.

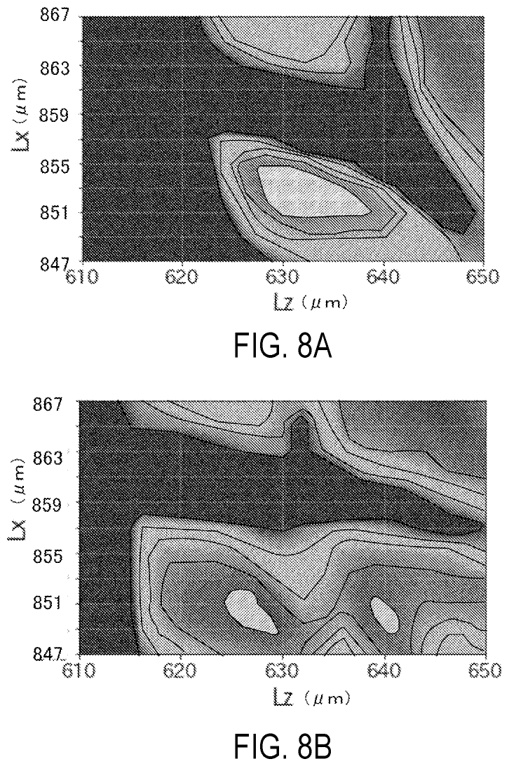

The reason that the crystal unit of the example has good properties compared with the comparative example is presumed as follows. FIG. 8A and FIG. 8B are explanatory drawings therefor, which are contour diagrams illustrating CI distributions with respect to Lx and Lz using the CI values in models for a finite element method analysis of the respective quartz-crystal vibrating pieces of the example and the comparative example where the dimension Lx and the dimension Lz are varied. The portions with diagonal lines in FIG. 8A and FIG. 8B are regions with the smallest CI.

In FIG. 8A and FIG. 8B, by viewing the relationship of the CI smallest regions (diagonal line regions) with respect to the regions with Lx of 849 to 857 μm and Lz of 625 to 645 μm or 636 to 643 μm claimed in this disclosure, it can be seen that, in the case of the example with the width reduction portion 111 in the Z′ dimension (FIG. 8A), the CI smallest region is included in the Lx to Lz range claimed in this disclosure. On the other hand, in the case of the comparative example without the width reduction portion in the Z′ dimension (FIG. 8B), it can be seen that while the CI smallest region is included in the Lx to Lz range claimed in this disclosure, it is narrow compared with the example, and moreover, is divided into two regions. In the comparative example, the reason why the CI smallest region is divided into two regions is that an obliquely propagating flexure vibration as one type of unnecessary vibration is combined with the main vibration. From FIG. 7B, FIG. 8A, and FIG. 8B, the width reduction portion 111 in the Z′ dimension can be said to be an effective structure in property improvement of the crystal unit.

### 4. Embodiment of 32 MHz Quartz-Crystal Vibrating Piece

In order to find a quartz-crystal vibrating piece having a novel structure that has an oscillation frequency of 32 MHz, can be housed within a small-sized package having an outside dimension with a long side dimension of approximately 1.2 mm and a short side dimension of approximately 1.0 mm, and has excellent properties, prototype experiments and simulations were performed similarly to the prototype experiments and simulations of the 24 MHz quartz-crystal vibrating piece described above. These prototypes, however, were made in several levels within a range from 630 μm to 650 μm of the Lx dimension and several levels within a range from 465 to 485 μm of the Lz dimension. At this time, the X dimension of the vibrator was 410 μm, the Z′ dimension was 386 μm, the X dimension of the excitation electrode 11 was 337 μm, and the Z′ dimension was 346 μm. The height d of the level difference to the thickness t of the vibrator was a value of d/t=0.1. The vibrator and the excitation electrode were disposed at positions where respective planar center points α (see FIG. 1C) of the vibrator and the excitation electrode were decentered by 64 μm in a direction of the distal end of the quartz-crystal vibrating piece with respect to a planar center point β (see FIG. 1C) of the quartz-crystal vibrating piece.

From these prototype experiments and simulations, it is found that, in the AT-cut quartz-crystal vibrating piece that has an oscillation frequency of 32 MHz and a planar shape in a rectangular shape, and includes the vibrator, the peripheral portion with a thickness thinner than that of the vibrator, and the level difference on each of the front and the back of the quartz-crystal vibrating piece being generated caused by the thickness difference between the vibrator and the peripheral portion, Lx is preferably in a range from 636 to 643 μm, Lz is preferably in a range from 472 to 479 μm, and d/t is preferably in a range of 0.094≤d/t≤0.11.

According to another aspect of this disclosure, there is provided an AT-cut quartz-crystal vibrating piece having an oscillation frequency of 32 MHz and a planar shape in a rectangular shape. The AT-cut quartz-crystal vibrating piece includes a vibrator, a peripheral portion having a thickness thinner than a thickness of the vibrator, and a level difference on each of a front and a back of the quartz-crystal vibrating piece. The level difference is generated caused by a thickness difference between the vibrator and the peripheral portion. When a dimension along an X-axis of a crystal of the quartz-crystal vibrating piece is defined as Lx, a dimension along a Z′-axis of the crystal of the quartz-crystal vibrating piece is defined as Lz, a thickness of the vibrator is defined as t, and a height of the level difference is defined as d, Lx is in a range from 636 to 643 μm, Lz is in a range from 472 to 479 μm, and d/t is in a range of 0.094≤d/t≤0.11.

A quartz crystal device as another aspect of this disclosure includes the quartz-crystal vibrating piece with a frequency of 24 MHz or the quartz-crystal vibrating piece with a frequency of 32 MHz described above and a container in which the quartz-crystal vibrating piece is mounted.

Note that the quartz crystal device mentioned in the disclosure of this application is, for example, a crystal unit including the quartz-crystal vibrating piece of this disclosure, what is called a temperature-sensor-provided crystal unit including the quartz-crystal vibrating piece of this disclosure and a temperature sensor (for example, a thermistor), a crystal controlled oscillator including the quartz-crystal vibrating piece of this disclosure and an oscillator circuit for this quartz-crystal vibrating piece, and a temperature compensation type crystal controlled oscillator including the quartz-crystal vibrating piece of this disclosure, an oscillator circuit for this quartz-crystal vibrating piece, a temperature sensor for temperature compensation, and a temperature compensation circuit.

In carrying out the disclosure of this quartz crystal device, the container preferably has an outer dimension with a long side dimension of 1.2 mm and a short side dimension of 1.0 mm. This is because a small-sized quartz crystal device required in the market can be provided. Note that the respective numerical values of the long side dimension of 1.2 mm and the short side dimension of 1.0 mm are in a range of a production allowable error of the container, for example, in a range of ±0.1 mm to the respective dimensions. Note that the quartz-crystal vibrating piece of this disclosure is surely allowed to be mounted and used in a container having an outer dimension larger than that with the long side dimension of 1.2 mm and the short side dimension of 1.0 mm.

With the quartz-crystal vibrating piece and the quartz crystal device according to this disclosure, the dimension Lx along the X-axis of the crystal, the dimension Lz along the Z′-axis of the crystal, the thickness t of the vibrator, and the height d of the level difference are in a predetermined range in the 24 MHz and 32 MHz quartz-crystal vibrating pieces that can be housed within the small-sized packages having the outer dimension with the long side dimension of approximately 1.2 mm and the short side dimension of approximately 1.0 mm, and therefore, property variations, for example, variations in crystal impedance (CI) of the quartz-crystal vibrating piece with respect to variations in ambient temperature can be restricted within a desired range. Accordingly, a quartz-crystal vibrating piece having a novel structure that can be housed within a small-sized package and is excellent in properties and a quartz crystal device using the same can be provided.

In the above-described embodiments, the respective X dimensions and Z′ dimensions of the vibrator and the excitation electrode and the positions of the vibrator and the excitation electrode with respect to the quartz-crystal vibrating piece have been described in one example for each frequency; however, the effects of this disclosure can be obtained with the respective X dimensions and Z′ dimensions of the vibrator and the excitation electrode and the positions of the vibrator and the excitation electrode with respect to the quartz-crystal vibrating piece not in the above-described example. That is, the respective X dimensions and Z′ dimensions of the vibrator and the excitation electrode and the positions of the vibrator and the excitation electrode with respect to the quartz-crystal vibrating piece can be changed in a range within which the object of this disclosure is not impaired.

The above-described embodiments have described the examples in which the container having the depressed portion is used as a container; however, the container may be a container configured of a flat plate-shaped base and a cap-shaped lid member that can contain the quartz-crystal vibrating piece.

The principles, preferred embodiment and mode of operation of the present invention have been described in the foregoing specification. However, the invention which is intended to be protected is not to be construed as limited to the particular embodiments disclosed. Further, the embodiments described herein are to be regarded as illustrative rather than restrictive. Variations and changes may be made by others, and equivalents employed, without departing from the spirit of the present invention. Accordingly, it is expressly intended that all such variations, changes and equivalents which fall within the spirit and scope of the present invention as defined in the claims, be embraced thereby.

What is claimed is:

1. An AT-cut quartz-crystal vibrating piece having an oscillation frequency of 24 MHz and a planar shape in a rectangular shape, comprising:
a vibrator;
a peripheral portion having a thickness thinner than a thickness of the vibrator; and
a level difference on each of a front and a back of the quartz-crystal vibrating piece, the level difference being generated caused by a thickness difference between the vibrator and the peripheral portion, wherein
when a dimension along an X-axis of a crystal of the quartz-crystal vibrating piece is defined as Lx, a dimension along a Z′-axis of the crystal of the quartz-crystal vibrating piece is defined as Lz, a thickness of the vibrator is defined as t, and a height of the level difference is defined as d,
Lx is in a range from 849 to 857 μm,
Lz is in a range from 625 to 645 μm, and
d/t is in a range of 0.094≤d/t≤0.11.

2. The quartz-crystal vibrating piece according to claim 1, wherein
the Lz is in a range from 630 to 638 μm.

3. The quartz-crystal vibrating piece according to claim 1, wherein
the quartz-crystal vibrating piece has angles θy1 and θy2 in a range from 85 to 90 degrees,
the angles θy1 and θy2 are formed by a distal-end-side short side of the quartz-crystal vibrating piece and long sides of the quartz-crystal vibrating piece, and
the distal-end-side short side is a short side opposite to a side to be adhered to a container with a securing member.

4. The quartz-crystal vibrating piece according to claim 1, further comprising
a width reduction portion that decreases in the dimension Lz of the quartz-crystal vibrating piece from a midpoint along the X-axis toward a securing-side short side as a short side of the quartz-crystal vibrating piece to be connected to a container with a securing member.

5. The quartz-crystal vibrating piece according to claim 1, further comprising
a width reduction portion that decreases in the dimension Lz of the quartz-crystal vibrating piece from a midpoint along the X-axis toward a securing-side short side as a short side of the quartz-crystal vibrating piece to be connected to a container with a securing member, wherein
when a contour in the X-axis direction of the width reduction portion is viewed, the contour is in a straight line, and
when the straight line is defined as a width reduction contour line Lg, an angle θ formed by the width reduction contour line Lg and the Z′-axis of the crystal is θ=93±2°.

6. The quartz-crystal vibrating piece according to claim 1, further comprising
a width reduction portion that decreases in the dimension Lz of the quartz-crystal vibrating piece from a midpoint along the X-axis toward a securing-side short side as a short side of the quartz-crystal vibrating piece to be connected to a container with a securing member, wherein
when a contour in the X-axis direction of the width reduction portion is viewed, the contour is in a straight line,
when the straight line is defined as a width reduction contour line Lg, an angle θ formed by the width reduction contour line Lg and the Z′-axis of the crystal is θ=93±2°, and
a portion in proximity to the securing-side short side of the quartz-crystal vibrating piece is a portion to be secured to the container with the securing member.

7. A quartz crystal device comprising:
the quartz-crystal vibrating piece according to claim 1; and
a container that contains the quartz-crystal vibrating piece.

8. The quartz crystal device according to claim 7, wherein
the container is in a rectangular shape in plan view and has an outer dimension with a long side dimension of 1.2 mm and a short side dimension of 1.0 mm.

9. An AT-cut quartz-crystal vibrating piece having an oscillation frequency of 32 MHz and a planar shape in a rectangular shape, comprising:
a vibrator;
a peripheral portion having a thickness thinner than a thickness of the vibrator; and
a level difference on each of a front and a back of the quartz-crystal vibrating piece, the level difference being generated caused by a thickness difference between the vibrator and the peripheral portion, wherein
when a dimension along an X-axis of a crystal of the quartz-crystal vibrating piece is defined as Lx, a dimension along a Z′-axis of the crystal of the quartz-crystal vibrating piece is defined as Lz, a thickness of the vibrator is defined as t, and a height of the level difference is defined as d,
Lx is in a range from 636 to 643 μm,
Lz is in a range from 472 to 479 μm, and
d/t is in a range of 0.094≤d/t≤0.11.

10. A quartz crystal device comprising:
the quartz-crystal vibrating piece according to claim 2; and
a container that contains the quartz-crystal vibrating piece.

11. The quartz crystal device according to claim 10, wherein
the container is in a rectangular shape in plan view and has an outer dimension with a long side dimension of 1.2 mm and a short side dimension of 1.0 mm.

12. A quartz crystal device comprising:
the quartz-crystal vibrating piece according to claim 3; and
a container that contains the quartz-crystal vibrating piece.

13. The quartz crystal device according to claim 12, wherein
the container is in a rectangular shape in plan view and has an outer dimension with a long side dimension of 1.2 mm and a short side dimension of 1.0 mm.

14. A quartz crystal device comprising:
the quartz-crystal vibrating piece according to claim 4; and
a container that contains the quartz-crystal vibrating piece.

15. The quartz crystal device according to claim 14, wherein
the container is in a rectangular shape in plan view and has an outer dimension with a long side dimension of 1.2 mm and a short side dimension of 1.0 mm.

16. A quartz crystal device comprising:
the quartz-crystal vibrating piece according to claim 5; and
a container that contains the quartz-crystal vibrating piece.

17. The quartz crystal device according to claim 16, wherein
the container is in a rectangular shape in plan view and has an outer dimension with a long side dimension of 1.2 mm and a short side dimension of 1.0 mm.

18. A quartz crystal device comprising:
the quartz-crystal vibrating piece according to claim 6; and
a container that contains the quartz-crystal vibrating piece.

19. The quartz crystal device according to claim 18, wherein
the container is in a rectangular shape in plan view and has an outer dimension with a long side dimension of 1.2 mm and a short side dimension of 1.0 mm.
